(19) United States
(12) Patent Application Publication
(10) Pub. No.: US 2025/0273616 A1
(43) Pub. Date: Aug. 28, 2025

(54) SEMICONDUCTOR DEVICE AND METHOD FOR MANUFACTURING SEMICONDUCTOR DEVICE

(71) Applicant: Renesas Electronics Corporation, Tokyo (JP)

(72) Inventor: Takuya OKADA, Tokyo (JP)

(21) Appl. No.: 18/951,791

(22) Filed: Nov. 19, 2024

(30) Foreign Application Priority Data
Feb. 27, 2024 (JP) 2024-027032

(51) Int. Cl. H01L 23/00; H01L 29/47; H01L 29/66; H01L 29/872

(52) U.S. Cl. CPC H01L 24/29; H01L 24/27; H10D 8/051; H10D 8/60; H10D 64/64; H01L 2224/2746; H01L 2224/29013; H01L 2224/29028; H01L 2224/29082; H01L 2924/01013; H01L 2924/05494; H01L 2924/07025; H01L 2924/10253; H01L 2924/12032; H01L 2924/3512

(57) ABSTRACT

A semiconductor device is provided, the semiconductor device including: a first electrode; an N-type semiconductor layer arranged on the first electrode; a P-type semiconductor layer arranged on the N-type semiconductor layer; a first insulating layer surrounding and partitioning a first region in plan view, arranged on the P-type semiconductor layer; a second electrode arranged on the P-type semiconductor layer; a second insulating layer arranged on the first insulating layer surrounding and partitioning the first region in plan view on the second electrode; a metal plating layer arranged on the second electrode; a solder layer arranged on the metal plating layer; and a clip arranged on the solder layer, and the first region is a region where the clip is joined with the metal plating layer.

### CROSS-REFERENCE TO RELATED APPLICATION

The disclosure of Japanese Patent Application No. 2024-027032 filed on Feb. 27, 2024, including the specification, drawings and abstract is incorporated herein by reference in its entirety.

### BACKGROUND

The present disclosure relates to a semiconductor device and a method for manufacturing a semiconductor device.

There is disclosed a technique listed below.

[Patent Document 1] Japanese Unexamined Patent Application Publication No. 2011-100811

The Patent Document 1 discloses a Schottky barrier diode not generating aluminum crack.

### SUMMARY

However, junction between a clip and a metal plating layer that is an electrode by using solder causes a problem that is unevenly-arranged solder, which results in inclined clip junction. Accordingly, an objective of the present disclosure is to provide a semiconductor device in which the clip and the metal plating layer that is the electrode are joined in parallel to each other.

Other objects and novel characteristics will become apparent from the description of the present specification and the drawings.

According to an embodiment, in the semiconductor device, the clip and the metal plating layer are joined to each other in a divided junction region.

According to the embodiment, the clip and the metal plating layer that is the electrode can be joined in parallel to each other.

### BRIEF DESCRIPTIONS OF THE DRAWINGS

FIG. 1 is a top view and an electric circuit diagram of a related-art semiconductor device.

FIG. 2 is a cross-sectional view of the related-art semiconductor device.

FIG. 3 is a cross-sectional view showing an issue of the related-art semiconductor device.

FIG. 4 is a top view and a cross-sectional view of a semiconductor device according to a first embodiment.

FIG. 5 is a cross-sectional view of the semiconductor device according to the first embodiment.

FIG. 6 is a cross-sectional view showing a current path of the semiconductor device according to the first embodiment.

FIG. 7 is a top view and a cross-sectional view of a semiconductor device according to a second embodiment.

FIG. 8 is a cross-sectional view showing a current path of the semiconductor device according to the second embodiment.

FIG. 9 is a top view and a cross-sectional view of a semiconductor device according to a third embodiment.

FIG. 10 is a cross-sectional view showing a current path of the semiconductor device according to the third embodiment.

FIG. 11 is a graph showing tendency of a loss and a V-F property according to the first, second and third embodiments.

### DETAILED DESCRIPTION

### Embodiments

Hereinafter, embodiments of the present invention will be described with reference to the accompanying drawings. However, the inventions according to claims are not limited to the following embodiments. Also, all structures explained in the embodiments are not limited to be indispensable means for solving The following description and drawings are the issues. appropriately omitted or simplified for clear explanation. The same components are denoted with the same reference signs throughout each drawing, and the repetitive description thereof is omitted as needed.

### Explanation for Structure and Issue of Related-Art Semiconductor Device

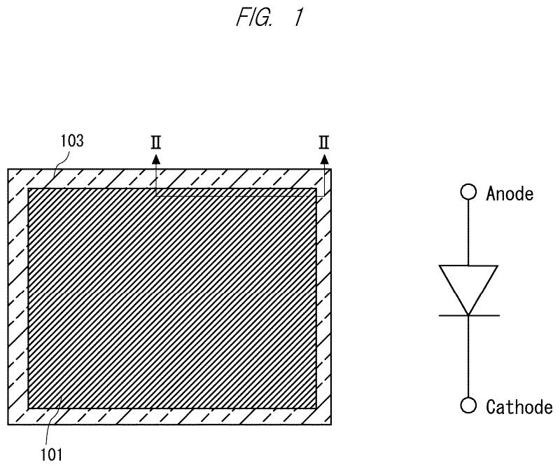

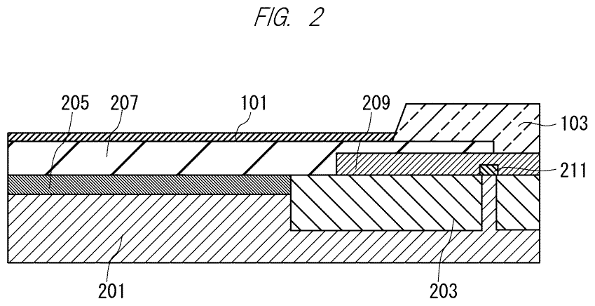

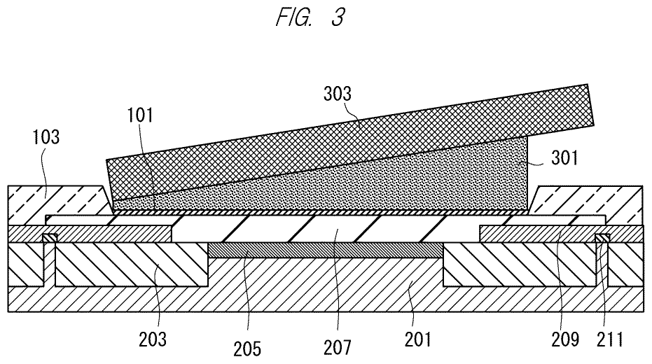

FIG. 1 is a top view and an electric circuit diagram of a related-art semiconductor device. FIG. 2 is a cross-sectional view of the related-art semiconductor device. FIG. 3 is a cross-sectional view showing an issue of the related-art semiconductor device. A structure and an issue of the related-art semiconductor device will be explained with reference to FIGS. 1 to 3. Each of the related-art and present-disclosed semiconductor devices is, for example, a power diode such as Schottky barrier diode.

As shown in FIG. 1, the semiconductor device has a rectangular plane shape. An anode that is a second electrode is formed on an upper surface of the semiconductor device, and a cathode that is a first electrode is formed on a bottom surface of the same. A metal plating layer 101 on the second electrode is covered with a second insulating layer 103 forming a first region in plan view.

FIG. 2 shows a cross-sectional surface II-II of FIG. 1. As shown in FIG. 2, an N-type semiconductor layer 201 is arranged on the first electrode of the bottom surface. The N-type semiconductor layer 201 is an N-type semiconductor layer made of, for example, a semiconductor substrate, particularly a silicon substrate or the like. A P-type well layer 203 and a P-type semiconductor layer 205 are arranged on the N-type semiconductor layer 201. The P-type well layer 203 is a region for defining each transistor region having an element isolation or CMOS structure. The P-type semiconductor layer 205 is a region for forming a channel. The P-type well layer 203 is doped with a P-type impurity of a higher concentration than that of the P-type semiconductor layer 205. Since the transistor is formed in regions other than a diode, the P-type semiconductor layer 205 forms a channel region. In the region for the diode that is the present-disclosed semiconductor device, P-N junction is formed between the P-type semiconductor layer 205 and the N-type semiconductor layer 201 to form the Schottky barrier diode.

A second electrode 207 is arranged on the P-type semiconductor layer 205. The second electrode 207 is made of, for example, a metal containing aluminum. A metal plating layer 101 made of OPM (Over Pad Metallization) is arranged on the second electrode 207. On the second electrode, the metal plating layer 101 is formed by, for example, an electro-plating method or an electroless-plating method.

A first insulating layer 209 is arranged on the P-type well layer 203. The first insulating layer 209 is made of, for example, PSG (Phosphorous Silicate Glass). The first insulating layer 209 is formed around an element in order to prevent the generation of the aluminum crack in the second element 207. A third insulating layer 211 that is a mask for well formation is arranged on the P-type well layer 203.

The second electrode 207 is arranged on the first insulating layer 209. A second insulating layer 103 is arranged in a portion on the second electrode 207 as well as the first insulating layer 209 in plan view. The second insulating layer 103 is made of, for example, polyimide.

As shown in FIG. 3, a clip 303 is joined to this semiconductor device by a solder layer 301. In this case, if the first region that is the region for junction of the clip 303 to the metal plating layer 101 is large, the solder layer 301 is unevenly arranged, and there is a risk that is failure of the arrangement of the clip 303 in parallel to the second electrode 207. The present-disclosed semiconductor device has been made for solving this issue.

### Explanation for Semiconductor Device According to First Embodiment

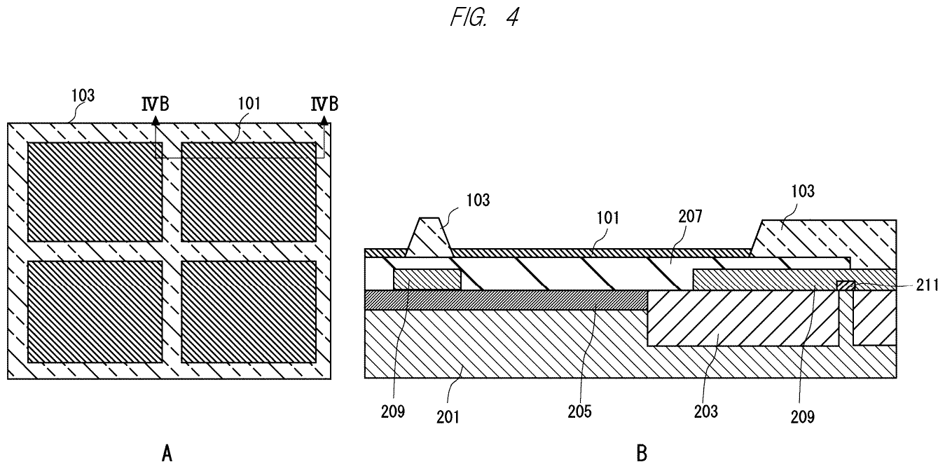

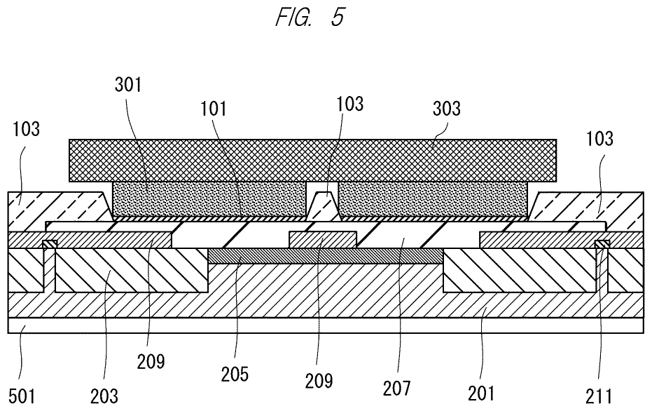

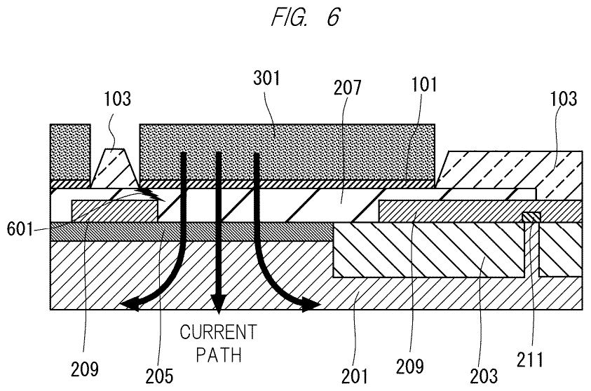

FIG. 4 is a top view and a cross-sectional view of a semiconductor device according to a first embodiment. FIG. 5 is a cross-sectional view of the semiconductor device according to the first embodiment. FIG. 6 is a cross-sectional view showing a current path of the semiconductor device according to the first The semiconductor device according to the first embodiment. embodiment will be explained with reference to FIGS. 4 to 6.

FIG. 4A is the top view of the semiconductor device according to the first embodiment, and FIG. 4B is the cross-sectional view IVB-IVB of FIG. 4A. As shown in FIGS. 4A and 4B, the semiconductor device according to the first embodiment is different from the related-art semiconductor device in that the metal plating layer 101 is partitioned by the second insulating layer 103. As shown in FIG. 4A, the first region is partitioned into a cross shape in plan view by the second insulating layer 103. The partitioned shape is not limited to the cross shape but also any shape such as a grid shape, a circular shape and a triangle shape including the cross shape in plan view. By such partitioning, the first region joined with the clip 303 is divided into a small shape, and therefore, the unevenness of the solder layer 301 is reduced. Therefore, the clip 303 is arranged in parallel to the second electrode 207.

As shown in FIG. 5, the semiconductor device includes a first electrode 501 that is a cathode. The N-type semiconductor layer 201 is arranged on the first electrode 501. The P-type semiconductor layer 205 is arranged on the N-type semiconductor The first insulating layer 209 surrounding and layer 201. partitioning the first region in plan view is arranged on the P-type semiconductor layer 205. The second electrode is arranged on the P-type semiconductor layer 205. The second insulating layer 103 is arranged on the first insulating layer 209 surrounding and partitioning the first region in plan view on the second electrode 207. The metal plating layer 101 is arranged on the second electrode 207. The solder layer 301 is arranged on the metal plating layer 101. The clip 303 is arranged on the solder layer 301. The first region described herein is a region where the clip is joined with the metal plating layer.

The first insulating layer 209 is below and overlapped with the second insulating layer 103 in plan view. The second insulating layer 103 may have the same shape as that of the first insulating layer 209 in plan view, or the region of the first insulating layer 209 may be larger as shown in FIG. 5. The second insulating layer 103 has a similar shape to that of the first insulating layer 209 in plan view. As shown in FIG. 6, even if the aluminum crack 601 in the second electrode 207 is generated, the first insulating layer 209 becomes a stopper, and the crack 601 does not spread. Therefore, the current path is not overheated, and the semiconductor device normally operates.

In a method for manufacturing the semiconductor device, first, the semiconductor substrate is prepared, and the first electrode 501 is formed on the bottom surface of the semiconductor substrate. Next, the N-type semiconductor layer 201 is formed in the semiconductor substrate. Next, the P-type well layer 203 is formed. The P-type well layer 203 is formed by the selective doping with the P-type impurity of the high concentration into the third insulating layer 211, and then, diffusing it. Next, the P-type semiconductor layer 205 is formed on the N-type semiconductor layer 201. The first insulating layer 209 surrounding and partitioning the first region in plan view is formed on the P-type semiconductor layer 205 on the upper surface of the semiconductor substrate. The second electrode 207 is formed on the first region of the P-type semiconductor layer 205 and on the first insulating layer 209. The second insulating layer 103 is formed on the first insulating layer 209 surrounding and partitioning the first region in plan view on the second electrode 207. The metal plating layer 101 is formed on the second electrode 207. The solder layer 301 is formed on the metal plating layer 101. Lastly, the clip 303 is arranged on the solder layer 301. The first region described herein is a region where the clip is joined with the metal plating layer.

The present-disclosed method for manufacturing the semiconductor device is the same as the related-art method for manufacturing the semiconductor device in the materials and the steps. Therefore, the present-disclosed method for manufacturing the semiconductor device can provide the semiconductor device in which the clip is arranged in parallel to the second electrode, without cost increase.

### Explanation for Semiconductor Device According to Second Embodiment

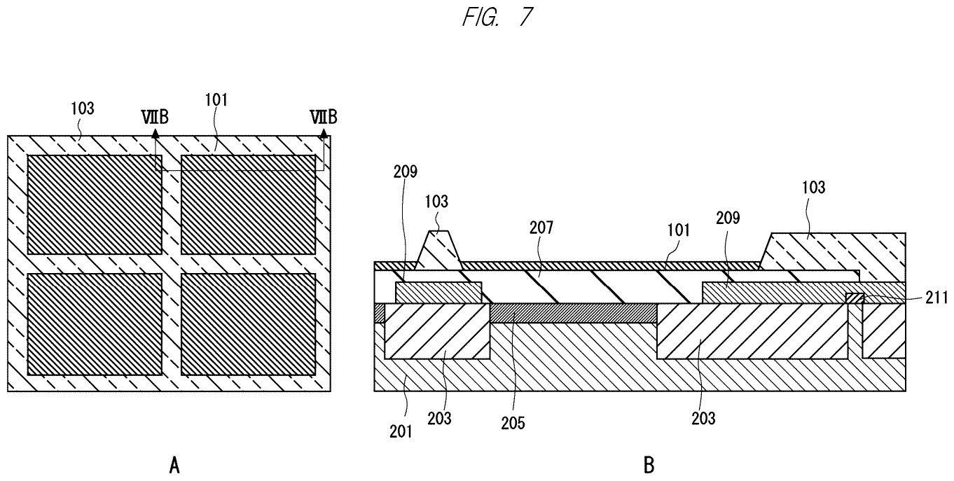

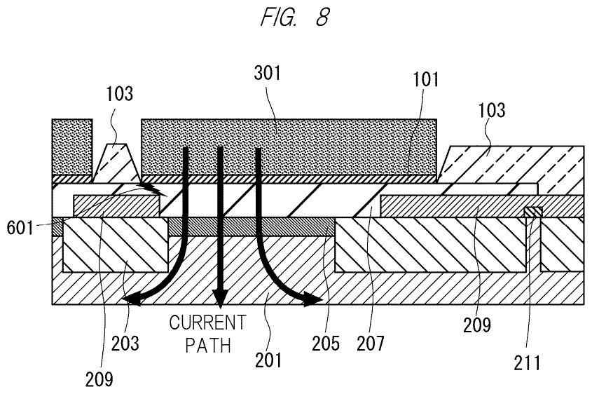

FIG. 7 is a top view and a cross-sectional view of a semiconductor device according to a second embodiment. FIG. 8 is a cross-sectional view showing a current path of the semiconductor device according to the second embodiment. The semiconductor device according to the second embodiment will be explained with reference to FIGS. 7 and 8.

FIG. 7A is the top view of the semiconductor device according to the second embodiment, and FIG. 7B is the cross-sectional view VIIB-VIIB of FIG. 7A. As shown in FIG. 7, the semiconductor device according to the second embodiment is different from the semiconductor device according to the first embodiment in that a P-type well layer 203 with the P-type impurity of the higher concentration than that of the P-type semiconductor layer is arranged below the first insulating layer 209 in plan view.

The P-type well layer 203 may have the same shape as that of the first insulating layer 209 in plan view, or the region of the first insulating layer 209 may be larger as shown in FIG. 7. The P-type well layer 203 has a similar shape to that of the first insulating layer 209 in plan view.

As shown in FIG. 8, the current path avoids the P-type well layer 203 because of the structure. Therefore, even if the crack 601 is generated, the overheating is prevented. Also, carriers are supplemented from the P-type well layer 203, and the V-F property (Forward Voltage) is reduced and is improved.

### Explanation for Semiconductor Device According to Third Embodiment

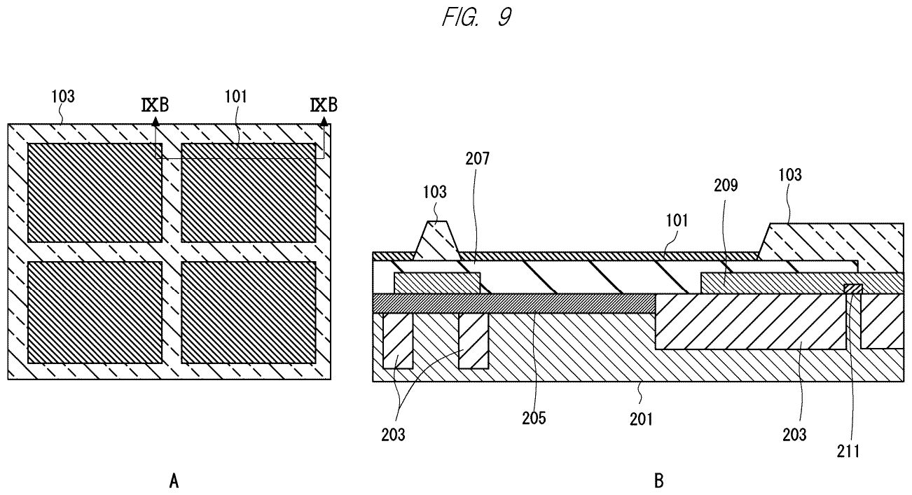

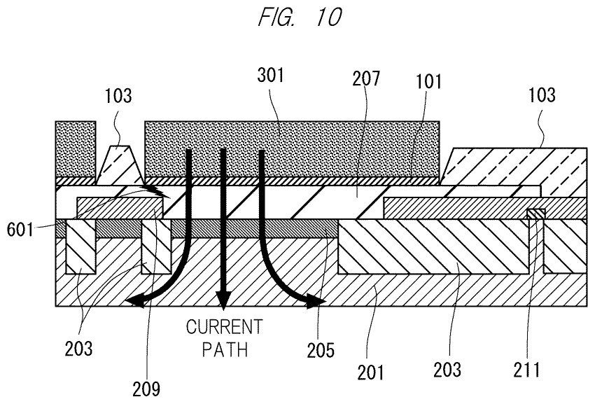

FIG. 9 is a top view and a cross-sectional view of a semiconductor device according to a third embodiment. FIG. 10 is a cross-sectional view showing a current path of the semiconductor device according to the third embodiment. The semiconductor device according to the third embodiment will be explained with reference to FIGS. 9 and 10.

FIG. 9A is the top view of the semiconductor device according to the third embodiment, and FIG. 9B is the cross-sectional view IXB-IXB of FIG. 9A. As shown in FIG. 9, the semiconductor device according to the third embodiment is different from the semiconductor device according to the first embodiment in that the P-type well layer 203 with the P-type impurity of the higher concentration than that of the P-type semiconductor layer is arranged on an end of the partitioning first insulating layer 209 in plan view.

The P-type well layer 203 has a shape along an outer circumference of the partitioning first insulating layer 209. Therefore, the P-type well layer 203 has a shape slightly protruding from the first insulating layer 209. The P-type well layer 203 has a region overlapping the partitioning first insulating layer 209 in plan view, but is not right below a center of the partitioning first insulating layer 209.

As shown in FIG. 10, the current path avoids the P-type well layer 203 because of the structure. Therefore, even if the crack 601 is generated, the overheating is prevented. Also, carriers are supplemented from the P-type well layer, and the V-F property is reduced and is improved.

### Comparison Among Properties of Semiconductor Devices According to First, Second and Third Embodiments

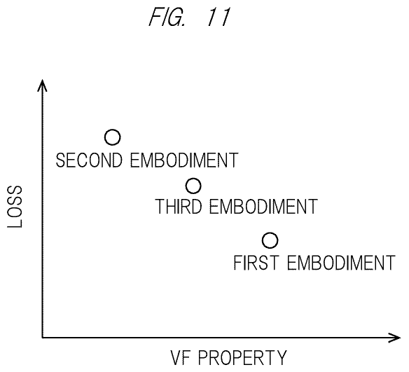

FIG. 11 is a graph showing tendency of a loss and the V-F property according to the first, second and third embodiments. The properties of the semiconductor devices according to the first, second and third embodiments are compared with one another with reference to FIG. 11.

As shown in FIG. 11, the semiconductor devices according to the second and third embodiments have the smaller and more improved V-F property than that of the semiconductor device according to the first embodiment. This is because the P-type well is increased to easily supplement the carriers. The reason why the V-F property of the semiconductor device according to the third embodiment is larger than that of the semiconductor device according to the second embodiment is that the P-type well layer is small.

On the other hand, the semiconductor devices according to the second and third embodiments have the larger loss than that of the semiconductor device according to the first embodiment. This is also because the P-type well is increased to easily supplement the carriers. The reason why the loss of the semiconductor device according to the third embodiment is smaller than that of the semiconductor device according to the second embodiment is that the P-type well layer is small. A relation between the V-F property and the loss is a trade-off relation, and the structure of the semiconductor device is determined by the necessary properties of the semiconductor device.

For example, the semiconductor devices according to the embodiments may be configured such that the conductivity types (p-type or n-type) of the semiconductor substrate, the semiconductor layer, the diffusion layer (diffusion region) and the like are inverted. Therefore, if either one of the n-type and the p-type is set as a first conductivity type while the other conductivity type is set as a second conductivity type, the first conductivity type may be the p-type while the second conductivity type may be the n-type, and conversely, the first conductivity type may be the n-type while the second conductivity type may be the p-type.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A semiconductor device comprising:
a first electrode;
an N-type semiconductor layer arranged on the first electrode;
a P-type semiconductor layer arranged on the N-type semiconductor layer;
a first insulating layer surrounding and partitioning a first region in plan view, arranged on the P-type semiconductor layer;
a second electrode arranged on the P-type semiconductor layer;
a second insulating layer arranged on the first insulating layer surrounding and partitioning the first region in plan view on the second electrode;
a metal plating layer arranged on the second electrode;
a solder layer arranged on the metal plating layer; and
a clip arranged on the solder layer,
wherein the first region is a region where the clip is joined with the metal plating layer.

2. The semiconductor device according to claim 1,
wherein the partitioning has a grid shape in plan view.

3. The semiconductor device according to claim 1,
wherein a P-type well layer with a P-type impurity of a higher concentration than a concentration of the P-type semiconductor layer is arranged below the partitioning first insulating layer in plan view.

4. The semiconductor device according to claim 1,
wherein a P-type well layer with a P-type impurity of a higher concentration than a concentration of the P-type semiconductor layer is arranged on an end of the partitioning first insulating layer in plan view.

5. The semiconductor device according to claim 1,
wherein the semiconductor device is a power diode.

6. The semiconductor device according to claim 1,
wherein the first insulating layer is made of PSG (Phosphorus Silicate Glass).

7. The semiconductor device according to claim 1,
wherein the second insulating layer is made of polyimide.

8. The semiconductor device according to claim 1,
wherein the second electrode contains aluminum.

9. The semiconductor device according to claim 1,
wherein the N-type semiconductor layer and the P-type semiconductor layer contain silicon.

10. A method for manufacturing a semiconductor device, comprising steps of:
forming a first electrode to be arranged on a bottom surface of a semiconductor substrate;
forming an N-type semiconductor layer to be arranged in the semiconductor substrate;
forming a P-type semiconductor layer to be arranged on the N-type semiconductor layer;
forming a first insulating layer surrounding and partitioning a first region in plan view, to be arranged on the P-type semiconductor layer on an upper surface of the semiconductor substrate;
forming a second electrode to be arranged on the first region of the P-type semiconductor layer and on the first insulating layer;
forming a second insulating layer to be arranged on the first insulating layer surrounding and partitioning the first region in plan view on the second electrode;
forming a metal plating layer to be arranged on the second electrode;
forming a solder layer to be arranged on the metal plating layer; and
arranging a clip to be arranged on the solder layer,
wherein the first region is a region where the clip is joined with the metal plating layer.

11. The method for manufacturing the semiconductor device according to claim 10,
wherein the partitioning has a grid shape in plan view.

12. The method for manufacturing the semiconductor device according to claim 10,
wherein a P-type well layer with a P-type impurity of a higher concentration than a concentration of the P-type semiconductor layer is arranged below the partitioning first insulating layer in plan view.

13. The method for manufacturing the semiconductor device according to claim 10,
wherein a P-type well layer with a P-type impurity of a higher concentration than a concentration of the P-type semiconductor layer is arranged on an end of the partitioning first insulating layer in plan view.

14. The method for manufacturing the semiconductor device according to claim 10,
wherein the semiconductor device is a power diode.

15. The method for manufacturing the semiconductor device according to claim 10,
wherein the first insulating layer is made of PSG (Phosphorus Silicate Glass).
